(19) United States
(12) Patent Application Publication
(10) Pub. No.: US 2026/0005038 A1
(43) Pub. Date: Jan. 1, 2026

(54) Through Substrate Via Formation on Patterned Substrates

(71) Applicant: Applied Materials, Inc., Santa Clara, CA (US)

(72) Inventors: Elise LAFFOSSE, Santa Clara, CA (US); Charles Thomas CARLSON, Leander, TX (US); Marvin Louis BERNT, Whitefish, MT (US)

(21) Appl. No.: 18/755,248

(22) Filed: Jun. 26, 2024

(51) Int. Cl. H01L 21/48; B23K 26/382; B23K 26/402; B23K 103/00; C23C 14/02; C23C 14/14; G03F 7/16

(52) U.S. Cl. CPC H01L 21/486; B23K 26/382; B23K 26/402; C23C 14/021; C23C 14/028; C23C 14/14; G03F 7/16; B23K 2103/30; B23K 2103/54

(57) ABSTRACT

Methods of processing a substrate are provided herein. In some embodiments, a method for processing a substrate includes: forming through via openings in a substrate from a back side of the substrate to a front side of the substrate, the substrate having front side metal interconnects disposed on the front side of the substrate that are exposed by the through via openings; and filling the through via openings to form through vias and forming back side metal interconnects on the back side of the substrate, wherein the back side metal interconnects are electrically coupled to the front side metal interconnects by the through vias.

### FIELD

Embodiments of the present disclosure generally relate to methods of processing a substrate, and more specifically, methods of filling through vias openings in a substrate.

### BACKGROUND

The demand for miniaturization, multifunctional and connected devices has been growing very fast. The miniaturization and functionality leads to the increased demand for high density and high bandwidth interconnections. The concept of 2.5-D and 3-D integrated circuit integration for packaging is a component to achieve next-generation performance requirements and to apply to commercial products. The ultrahigh number of I/O connections is becoming available using substrates such as interposers. Current integration techniques first form via openings through a substrate before filling the substrate (typically with conductive material). However, under such techniques, the via openings have no bottoms and thus the bottoms of the via openings need to be closed before a material is deposited in the via openings.

Accordingly, the inventors have provided improved methods of processing a substrate.

### SUMMARY

Methods of processing a substrate are provided herein. In some embodiments, a method for processing a substrate includes: forming through via openings in a substrate from a back side of the substrate to a front side of the substrate, the substrate having front side metal interconnects disposed on the front side of the substrate that are exposed by the through via openings; and filling the through via openings to form through vias and forming back side metal interconnects on the back side of the substrate, wherein the back side metal interconnects are electrically coupled to the front side metal interconnects by the through vias.

In some embodiments, a method for processing a substrate includes: patterning a front side of the substrate to form front side copper interconnects; forming through via openings in a substrate from a back side of the substrate to the front side of the substrate; forming a first layer on the back side of the substrate, where the first layer includes an opening to expose the through via openings; and using a copper plating process to fill the through via openings to form through vias and to form back side copper interconnects on the back side of the substrate, wherein the back side copper interconnects are electrically coupled to the front side copper interconnects by the through vias.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart of a method of processing a substrate in accordance with at least some embodiments of the present disclosure.

FIG. 2 depicts a schematic side view of a substrate with front side interconnects in accordance with at least some embodiments of the present disclosure.

FIG. 3 depicts a schematic side view of a substrate with via openings in accordance with at least some embodiments of the present disclosure.

FIG. 4A depicts a schematic side view of a substrate after performing a lithography and etch process on a back side of the substrate in accordance with at least some embodiments of the present disclosure.

FIG. 4B depicts a schematic side view of a substrate after depositing a seed layer on a back side of the substrate in accordance with at least some embodiments of the present disclosure.

FIG. 4C depicts a schematic side view of a substrate after depositing a conductive material in through via openings in a substrate and a back side of the substrate in accordance with at least some embodiments of the present disclosure.

FIG. 4D depicts a schematic side view of a substrate after a planarization process in accordance with at least some embodiments of the present disclosure.

FIG. 5A depicts a schematic side view of a substrate after depositing a liner layer and performing a lithography process on a back side of the substrate in accordance with at least some embodiments of the present disclosure.

FIG. 5B depicts a schematic side view of a substrate after performing a metal deposition process and photoresist removal process on a back side of the substrate in accordance with at least some embodiments of the present disclosure.

FIG. 5C depicts a schematic side view of a substrate after depositing a dielectric layer on the back side of the substrate in accordance with at least some embodiments of the present disclosure.

FIG. 6A depicts a schematic side view of a substrate with front side interconnects and having a front side seed layer in accordance with at least some embodiments of the present disclosure.

FIG. 6B depicts a schematic side view of a substrate filling via openings in accordance with at least some embodiments of the present disclosure.

FIG. 6C depicts a schematic side view of a substrate after removing a front side seed layer in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods of processing a substrate are provided herein. The methods provided herein generally comprises forming through via openings through a substrate after a front side of the substrate has been patterned. The pattern may comprise one or more layers made of one or more materials. The processing of the substrate subsequently continues with a fill process of the through via openings. The patterned front side advantageously reduces process steps to close the bottom of the through via, which can make the overall substrate integration cheaper, more robust, and with better yield. The methods provided herein may also provide back side patterning, at least a portion of which can be completed with the fill process. Processing the through via opening fill together with a first layer of the back side patterning of the substrate can advantageously reduce the number of process steps and can reduce the stress of the different patterned layers on the back side.

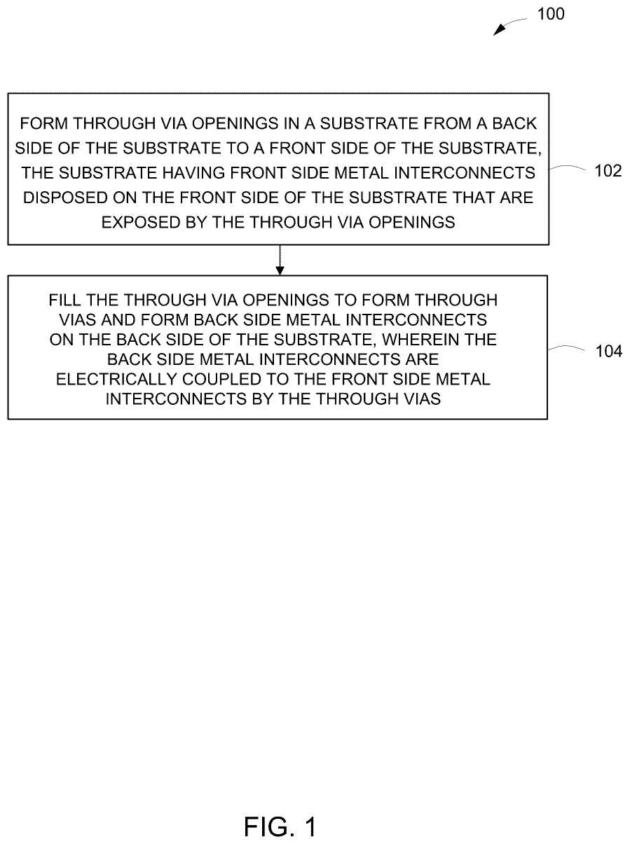

FIG. 1 depicts a flow chart of a method 100 of processing a substrate (e.g., substrate 202) in accordance with at least some embodiments of the present disclosure. At 102, the method 100 includes forming through via openings (e.g., through via openings 302) in a substrate from a back side (e.g., back side 208) of the substrate to a front side (e.g., front side 206) of the substrate, the substrate having a pattern comprising front side metal interconnects (e.g., front side metal interconnects 210) disposed on the front side of the substrate that are exposed by the through via openings. In some embodiments, the through via openings are formed by a suitable method. For example, the through via openings may be formed by etching, such as chemical etching or laser drilling.

In some embodiments, forming the front side metal interconnects comprises depositing a first dielectric layer (e.g., first dielectric layer 212) on the front side of the substrate, etching the first dielectric layer to form first dielectric vias (e.g., first dielectric vias 216), and depositing first metal interconnects (e.g., front side metal interconnects 210) in the first dielectric vias. In some embodiments, the method 100 includes depositing a seed layer in the first dielectric vias prior to depositing the first metal interconnects.

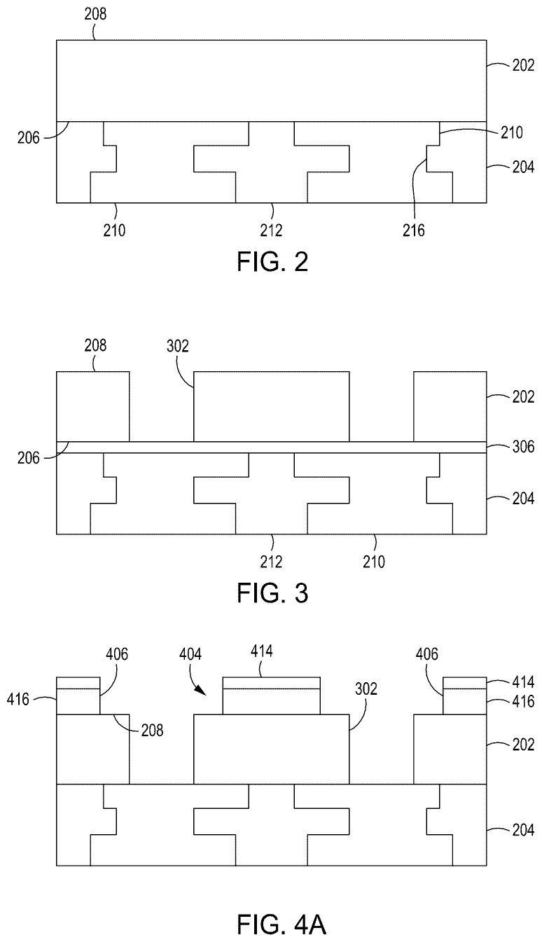

FIG. 2 depicts a schematic side view of a substrate with front side interconnects in accordance with at least some embodiments of the present disclosure. The substrate 202 includes a front side 206 and a back side 208 opposite the front side 206. The substrate can be glass, silicon, an organic material, or other suitable material. In some embodiments, the substrate is a 300 mm glass wafer. A front side pattern 204 is disposed on the front side 206 of the substrate 202.

The front side pattern 204 on the front side of the substrate can be made of different materials, with different dimensions. For example, the front side pattern 204 may comprise front side metal interconnects 210 disposed in a first dielectric layer 212. The front side metal interconnects 210 are disposed in first dielectric vias 216 formed in the first dielectric layer 212. The first dielectric vias 216 may have a non-uniform width through the front side pattern 204. The first dielectric vias 216 may be formed via multiple deposition, etching, and lithography processes. For example, to form the front side metal interconnects 210 depicted in FIG. 2, the first dielectric layer 212 may be formed via deposition and etching of multiple sub-layers. In some embodiments, a lithography process may be used to pattern the first dielectric vias 216 along each of the multiple sub-layers.

FIG. 3 depicts a schematic side view of a substrate with through via openings 302 in accordance with at least some embodiments of the present disclosure. The through via openings 302 extend from the front side 206 to the back side 208. In some embodiments, the method 100 further comprises forming a reflective layer 306 between the substrate 202 and the front side metal interconnects 210. The reflective layer 306 may comprise a metal layer configured to reduce or prevent blow through of the front side metal interconnects during the formation of the through via openings 302, for example via laser drilling. In some embodiments, the reflective layer 306 comprises copper, gold, silver, or aluminum. The reflective layer 306 is generally formed or deposited on the substrate 202 prior to forming the front side pattern 204.

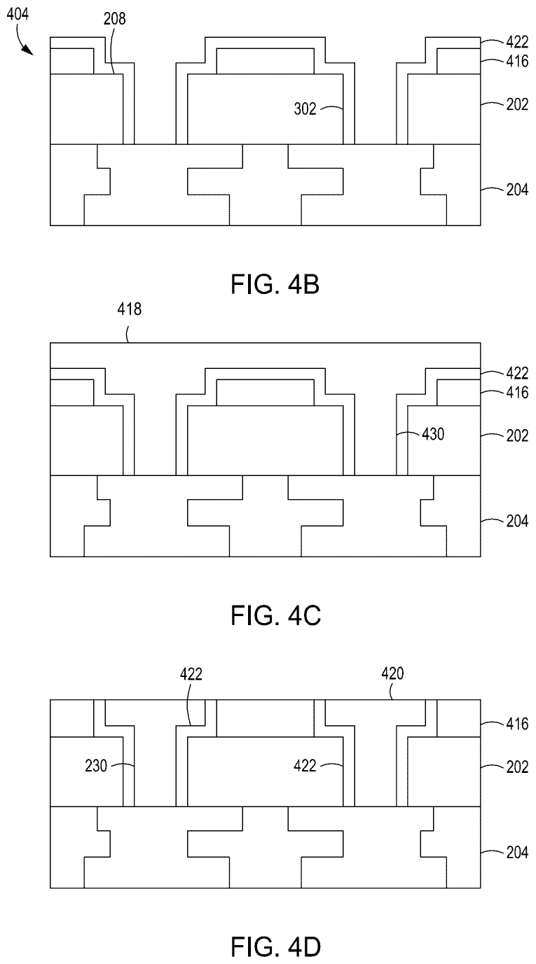

At 104, the method 100 includes filling the through via openings to form through vias (e.g., through vias 430 discussed below with respect to FIG. 4C) and forming back side metal interconnects (e.g., back side metal interconnects 420 discussed below with respect to FIG. 4D) on the back side of the substrate, wherein the back side metal interconnects are electrically coupled to the front side metal interconnects by the through vias. In some embodiments, forming back side metal interconnects on the back side of the substrate, comprises forming a first layer (e.g., first layer 404) on the back side of the substrate, where the first layer includes openings (e.g., openings 406) to expose the through via openings; and depositing back side metal interconnects in the through via openings and in the opening in the first layer to electrically couple the back side metal interconnects with the front side metal interconnects. The front side pattern 204 advantageously provides a closed back to the through via openings 302 for the deposition of the backside metal interconnects. In some embodiments, the back side metal interconnects comprise copper or magnetic alloys.

In some embodiments, forming the first layer comprises depositing a second dielectric layer (e.g., second dielectric layer 416) on the back side of the substrate, depositing a photoresist pattern on the second dielectric layer via a lithography process; etching the second dielectric layer at locations not covered by the photoresist pattern to form the opening to expose the through via openings; removing the photoresist pattern, and depositing a seed layer (e.g., seed layer 422) in the through via openings and the second dielectric layer. In some embodiments, the method 100 includes filling the through via openings with a PVD deposition process. In some embodiments, the through via openings are filled via a metal plating process. In some embodiments, the through via openings are filled via a copper metal plating process. In some embodiments, the seed layer comprises a same material as the back side metal interconnects.

FIG. 4A depicts a schematic side view of a substrate 202 after etching a first layer 404 on a back side of the substrate in accordance with at least some embodiments of the present disclosure. The first layer 404 includes a second dielectric layer 416 disposed on the back side 208 of the substrate 202. A resist 414 having a desired pattern is disposed on the second dielectric layer 416. The design pattern in the resist 414 is used to form openings 406 in the second dielectric layer 416. The openings 406 are aligned with the through via openings 302 to expose the through via openings 302. In some embodiments, the openings 406 are larger in width or diameter than the through via openings 302.

FIG. 4B depicts a schematic side view of a substrate after depositing a seed layer 422 on a back side of the substrate in accordance with at least some embodiments of the present disclosure. In some embodiments, the resist 414 is removed prior to depositing the seed layer 422. In some embodiments, the seed layer 422 covers sidewalls of the through via openings 302. In some embodiments, the seed layer 422 covers exposed portions of the back side 208 of the substrate 202. In some embodiments, the seed layer 422 covers exposed portions of the second dielectric layer 416.

FIG. 4C depicts a schematic side view of a substrate 202 after depositing a conductive material in through via openings and back side of a substrate in accordance with at least some embodiments of the present disclosure. The through via openings 302 are generally filled with the conductive material 418 to form through vias 430. The conductive material 418 deposited on the back side 208 of the substrate 202 is generally formed via the same process as the process for filling the through via openings 302. In some embodiments, the through vias 430 are formed with a metal plating process, such as copper plating. The seed layer 422 advantageously facilitates fill of the through via openings 302 via the plating process. The seed layer 422 also advantageously facilitates deposition of the conductive material 418 atop the seed layer 422 on the back side 208 of the substrate 202 and the sides and top of the second dielectric layer 416.

FIG. 4D depicts a schematic side view of a substrate after a planarization process in accordance with at least some embodiments of the present disclosure. In some embodiments, the method 100 includes, as shown in FIG. 4D, planarizing at least one of the second dielectric layer 416 or the conductive material 418 on the back side 208 of the substrate 202 to form the metal interconnects 420. Planarizing may be done via a suitable method such as chemical mechanical polishing (CMP). Further processing or layering may be conducted atop the planarized second dielectric layer 416 with the back side metal interconnects 420 disposed therein.

In some embodiments, the method 100 includes depositing a liner layer (e.g., liner layer 504) on the back side of the substrate and sidewalls of the through via openings, and wherein forming the first layer comprises depositing a photoresist pattern (e.g., photoresist pattern 508) via a lithography process on portions of the liner layer disposed atop the back side of the substrate. In some embodiments, the liner layer comprises a same material as the back side metal interconnects. The photoresist pattern includes openings (e.g., openings 512) aligned with the through via openings to expose the through via openings. In some embodiments, the method 100 comprises removing the photoresist pattern after depositing the back side metal interconnects. In some embodiments, the method 100 includes depositing a second dielectric layer (e.g., second dielectric layer 530) on the front side of the substrate after removing the photoresist.

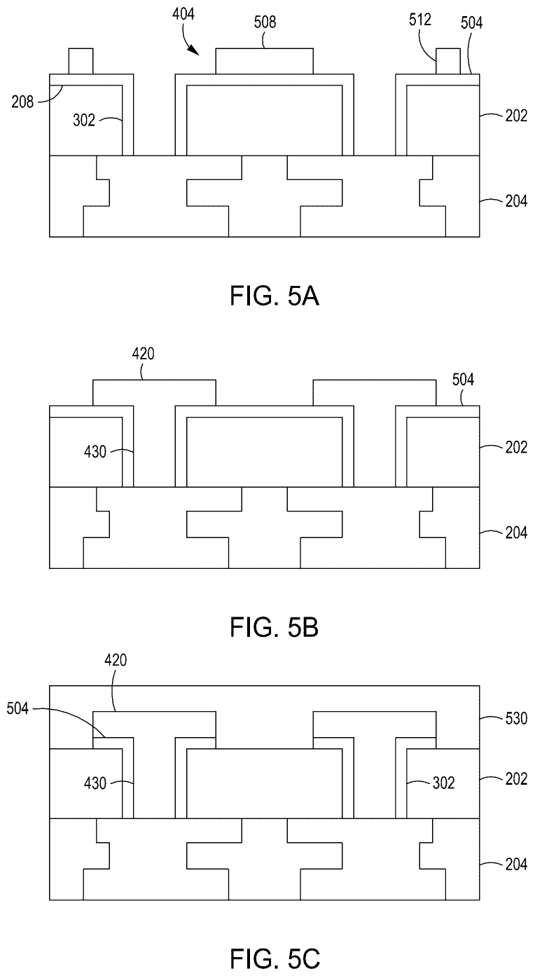

FIG. 5A depicts a schematic side view of a substrate 202 after depositing a liner layer 504 and performing a lithography process on a back side 208 of the substrate in accordance with at least some embodiments of the present disclosure. In some embodiments, after forming the through via openings 302, exposed surfaces of the substrate 202 are covered with the liner layer 504. In some embodiments, the first layer 404 comprises a photoresist pattern 508 with a desired pattern of openings 512. The openings 512 are configured to expose the through via openings 302. In some embodiments, the openings 512 are wider or have a greater diameter than the through via openings 302. The openings 512 are suitably dimensioned for back side metal interconnects 420 to be deposited therein.

FIG. 5B depicts a schematic side view of a substrate 202 after performing a metal deposition process and photoresist removal process on a back side 208 of the substrate in accordance with at least some embodiments of the present disclosure. The metal deposition process forms the through vias 430 and the back side metal interconnects 420 having the desired geometry. Once the back side metal interconnects 420 are formed, the photoresist pattern 508 is removed.

FIG. 5C depicts a schematic side view of a substrate 202 after depositing a second dielectric layer 530 on the back side of 208 the substrate 202 in accordance with at least some embodiments of the present disclosure. The second dielectric layer 530 is disposed on the exposed portions of the back side 208 and the exposed portions of the back side metal interconnects 420. In some embodiments, the second dielectric layer 530 may be planarized to expose the back side metal interconnects 420.

In some embodiments, the method 100 includes depositing a seed layer (e.g., front side seed layer 610) on the front side metal interconnects 210 prior to forming the through via openings 302. The seed layer advantageously facilitates performing a metal plating process in the through via openings 302 without a seed or liner layer disposed in the through via openings. In some embodiments, the method 100 includes removing the seed layer on the front side metal interconnects 210 after depositing the back side metal interconnects 420. In some embodiments, forming the back side metal interconnects 420 via the front side seed layer 610 can advantageously fill multi-diameter through via openings 302 which may be more challenging with a seed or liner layer disposed in the through via openings 302.

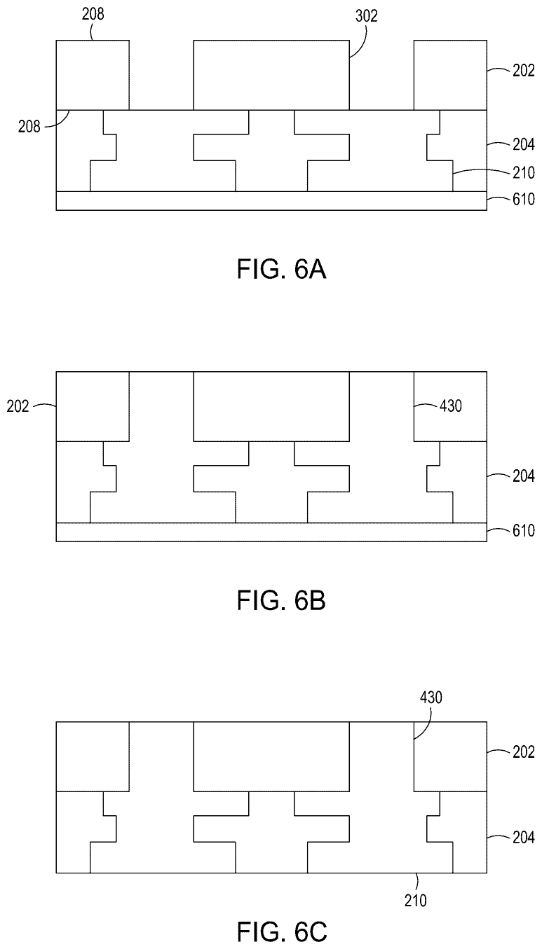

FIG. 6A depicts a schematic side view of a substrate 202 with front side metal interconnects 210 and having a front side seed layer 610 in accordance with at least some embodiments of the present disclosure. The front side seed layer 610 can be coupled to an electric current to facilitate a plating process in the through via openings 302 and the back side 208 of the substrate 202. FIG. 6B depicts a schematic side view of a substrate 202 after filling the through via openings 302 in accordance with at least some embodiments of the present disclosure. FIG. 6C depicts a schematic side view of a substrate 202 after removing a front side seed layer 610 in accordance with at least some embodiments of the present disclosure. Removing the front side seed layer 610 exposed the front side metal interconnects 210 and prepares the substrate 202 for further processing.

While the foregoing is directed to embodiments of the present disclosure, other and further embodiments of the disclosure may be devised without departing from the basic scope thereof.

1. A method for processing a substrate, comprising:
forming through via openings in a substrate from a back side of the substrate to a front side of the substrate, the substrate having front side metal interconnects disposed on the front side of the substrate that are exposed by the through via openings; and
filling the through via openings to form through vias and forming back side metal interconnects on the back side of the substrate, wherein the back side metal interconnects are electrically coupled to the front side metal interconnects by the through vias.

2. The method of claim 1, further comprising forming the front side metal interconnects by:
depositing a first dielectric layer on the front side of the substrate;
etching the first dielectric layer to form first dielectric vias; and
depositing first metal interconnects in the first dielectric vias.

3. The method of claim 2, further comprising depositing a seed layer in the first dielectric vias prior to depositing the first metal interconnects.

4. The method of claim 1, wherein filling the through via openings to form through vias and forming back side metal interconnects on the back side of the substrate, comprises:
forming a first layer on the back side of the substrate, where the first layer includes an opening to expose the through via openings; and
depositing a metal fill in the through via openings and a metal fill in the opening in the first layer to form the back side metal interconnects.

5. The method of claim 4, wherein depositing the back side metal interconnects comprises performing a copper plating process without a seed layer disposed in the through via openings.

6. The method of claim 4, wherein forming the first layer comprises:
depositing a second dielectric layer on the back side of the substrate;
depositing a photoresist pattern on the second dielectric layer via a lithography process;
etching the second dielectric layer at locations not covered by the photoresist pattern to form the opening to expose the through via openings;
removing the photoresist pattern; and
depositing a seed layer in the through via openings and the second dielectric layer.

7. The method of claim 6, further comprising planarizing the second dielectric layer and the back side metal interconnects after depositing the back side metal interconnects.

8. The method of claim 4, further comprising depositing a liner layer on the back side of the substrate and the through via openings, and wherein forming the first layer comprises depositing a photoresist pattern via a lithography process on portions of the liner layer disposed atop the back side of the substrate, and further comprising removing the photoresist pattern after depositing the back side metal interconnects.

9. The method of claim 8, further comprising depositing a second dielectric layer on the front side of the substrate after removing the photoresist pattern.

10. The method of claim 1, wherein the through via openings are formed via laser drilling.

11. The method of claim 1, wherein the back side metal interconnects comprise copper or magnetic alloys.

12. The method of claim 1, further comprising forming a reflective layer between the substrate and the front side metal interconnects.

13. The method of claim 1, wherein the substrate comprises an organic material, silicon, or glass.

14. A method for processing a substrate, comprising:
patterning a front side of the substrate to form front side copper interconnects;
forming through via openings in a substrate from a back side of the substrate to the front side of the substrate;
forming a first layer on the back side of the substrate, where the first layer includes an opening to expose the through via openings; and
using a copper plating process to fill the through via openings to form through vias and to form back side copper interconnects on the back side of the substrate, wherein the back side copper interconnects are electrically coupled to the front side copper interconnects by the through vias.

15. The method of claim 14, wherein forming the through via openings in the substrate comprises etching the substrate with a laser.

16. The method of claim 14, wherein patterning the front side of the substrate comprises depositing a first dielectric layer on the front side, and further comprising:
depositing a liner layer on sidewalls of the through via openings and on the back side of the substrate prior to forming the back side copper interconnects; and
wherein forming the first layer comprises:
depositing a photoresist pattern via a lithography process on portions of the liner layer disposed atop the back side of the substrate, or
(i) depositing a second dielectric layer on the back side prior to depositing the liner layer;
(ii) depositing a photoresist pattern on the second dielectric layer via a lithography process;
(iii) etching the second dielectric layer at locations not covered by the photoresist pattern to form the opening to expose the substrate via; and
(iv) removing the photoresist pattern.

17. The method of claim 14, further comprising planarizing the first layer and the back side copper interconnects after forming the back side copper interconnects.

18. The method of claim 14, wherein forming the through via openings through the substrate comprises etching the substrate with a laser.

19. The method of claim 14, further comprising:
depositing a seed layer on the front side copper interconnects prior to forming the through via openings; and
removing the seed layer after depositing the back side copper interconnects.

20. The method of claim 14, further comprising forming a reflective layer between the substrate and the front side copper interconnects.
